(19) United States
(12) Patent Application Publication
(10) Pub. No.: US 2024/0329392 A1
(43) Pub. Date: Oct. 3, 2024

(54) OPTICAL SYSTEM DESIGNING SYSTEM, OPTICAL SYSTEM DESIGNING METHOD, LEARNED MODEL, AND INFORMATION RECORDING MEDIUM

(71) Applicant: OLYMPUS CORPORATION, Tokyo (JP)

(72) Inventor: Tomohiro ODAIRA, Tokyo (JP)

(73) Assignee: OLYMPUS CORPORATION, Tokyo (JP)

(21) Appl. No.: 18/741,078

(22) Filed: Jun. 12, 2024

Related U.S. Application Data
(63) Continuation of application No. PCT/JP2022/001130, filed on Jan. 14, 2022.

(51) Int. Cl. G02B 27/00; G06F 30/27

(52) U.S. Cl. CPC G02B 27/0012; G06F 30/27

(57) ABSTRACT

An optical system designing system for designing an optical system through reinforcement learning has a storage unit storing at least information relating to a learned model, a processor and an input unit that inputs optical design information and a target value to the processor. The learned model is a learning model configured as a function whose parameters have been updated in such a way as to compute a design solution towards the optical design information of the optical system that is based on the target value. The processor executes a macro process of at least one of the actions of changing the number of lenses included in the optical design information, changing a lens material, changing cementing of lenses, changing the location of a stop, and selecting a spherical lens or an aspherical lens and performs an optical system optimization process using weights for aberrations computed by Bayesian optimization as correction values. The processor computes the design information after the execution of the macro process and a reward value based on the target value. Then, the processor computes an evaluation value based on the optical design information and the reward value and computes a design solution based on the target value.

### CROSS REFERENCE TO RELATED APPLICATION

The present application is a continuation application of PCT/JP2022/1130 filed on Jan. 14, 2022, the entire contents of which are incorporated herein by reference.

### BACKGROUND OF THE INVENTION

### Field of the Invention

The present invention relates to an optical system designing system, an optical system designing method, a learned model, and an information recording medium.

### Description of the Related Art

### BACKGROUND ART

When designing optical systems, optical designers evaluate designs from various viewpoints such as specifications, cost, and optical performance. To pick promising design plans, optical designers need to create many design plans.

Optical designers improve optical designs by adjusting various parameters such as the curvature radius of lenses, surface distances, refractive indices, and Abbe numbers mainly using optimization functions provided by optical design software. In this way, optical designers create many design plans.

The optimization function of optical design software most commonly uses a method based on the damped least squares using gradients (for example, see Non-Patent Literature 1 cited below). Other optimization methods that do not use gradients are also known nowadays, examples of which include Bayesian optimization, genetic algorithm (for example, see Non-Patent Literature 2 cited below), annealing method, Nelder-Mead method, and particle swarm optimization.

Optical designers create many design plans selectively using the algorithms mentioned above on the basis of their own experiences and knowledge relating to optical design.

### CITATION LIST

### Non-Patent Literature

Non-Patent Literature 1: Masaki Isshiki “Global Optimization in Lens Design”, Japanese Journal of Optics: Publication of the Optical Society of Japan, Volume 27, Issue 9, 1998.
Non-Patent Literature 2: Masaharu Tanaka et al. “Lens System Design by A Two Stage GA “Solid EMO””, Transaction of the Japanese Society for Artificial Intelligence, Volume 23, Issue 3, 2008.

### SUMMARY OF THE INVENTION

An optical system designing system according to at least some embodiments of the present invention is configured to design an optical system through reinforcement learning. The optical system designing system comprises a storage unit storing at least information relating to a learned model, a processor, and an input unit that inputs optical design information relating to a design of the optical system and a target value to the processor. The learned model is a learning model configured as a function whose parameters have been updated in such a way as to compute a design solution towards the optical design information of the optical system that is based on the target value. The processor is configured to execute the step of: executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values; computing the design information after the execution of the macro process and a reward value based on the target value; computing an evaluation value based on the optical design information and the reward value; and computing a design solution based on the target value in the optical design information.

An optical system designing method according to at least some embodiments of the present invention is an optical system designing method for designing an optical system through reinforcement learning. The optical system designing method comprises the steps of: storing at least information relating to a learned model; obtaining optical design information relating to a design of the optical system and a target value, the learned model being a learning model configured as a function whose parameters have been updated in such a way as to compute a design solution towards the optical design information of the optical system that is based on the target value; executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values; computing the optical design information after the execution of the macro process and a reward value based on the target value; computing an evaluation value based on the optical design information and the reward value; and computing a design solution towards the optical design information of the optical system that is based on the target value.

A learned model according to at least some embodiments of the present invention is configured to allow a computer configured to design an optical system through reinforcement learning to operate. The learned model is learned by: obtaining optical design information relating to a design of an optical system and a target value; executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values; computing the optical design information after the execution of the macro process and a reward value based on the target value; performing an exploration to compute an evaluation value based on the optical design information and the reward value; and updating parameters of a learning model based on the evaluation value in such a way as to maximize the evaluation value.

An information storage medium according to at least some embodiments of the present invention stores a learned model and a program. The program is configured to cause a computer to execute the step of: inputting optical design information relating to a design of an optical system and a target value; executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values; computing the optical design information after the execution of the macro process and a reward value based on the target value; computing an evaluation value based on the optical design information and the reward value; and computing a design solution towards the optical design information of the optical system that is based on the target value using the learned model. The learned model is a learning model configured as a function whose parameters have been updated in such a way as to compute a design solution towards the optical design information of the optical system that is based on the target value.

### BRIEF DESCRIPTION OF THE DRAWINGS

FIG. 1 is a diagram showing the configuration of an optical system designing system according to an embodiment;

FIG. 2 is a diagram showing the configuration of a learning apparatus in the optical system designing system;

FIG. 3 is a flow chart showing the outline of an optical system designing method according to the embodiment;

FIG. 4 is a flow chart of an exploration phase in the optical system designing method according to the embodiment;

FIGS. 5A, 5B, 5C, 5D, 5E, 5F, 5G, and 5H illustrate macro processes;

FIG. 6 is a flow chart of Bayesian optimization used in the optical system designing method according to the embodiment;

FIGS. 7A, 7B, 7C, 7D, and 7E are diagrams illustrating the Bayesian optimization;

FIG. 8 is a flow chart of a learning phase in the optical system designing method;

FIG. 9 is a flow chart of iteration of the exploration phase and the learning phase;

FIG. 10A is a cross sectional view of the lenses in an initial optical system, and FIGS. 10B, 10C, 10D, 10E, and 10F are spot diagrams of this optical system at different image heights;

FIG. 11A is a cross sectional view of the lenses in an optical system according to a first optimized design solution, and FIGS. 11B, 11C, 11D, 11E, and 11F are spot diagrams of this optical system at different image heights;

FIG. 12A is a cross sectional view of the lenses in an optical system according to a second optimized design solution, and FIGS. 12B, 12C, 12D, 12E, and 12F are spot diagrams of this optical system at different image heights;

FIG. 13A is a cross sectional view of the lenses in an optical system according to a third optimized design solution, and FIGS. 13B, 13C, 13D, 13E, and 13F are spot diagrams of this optical system at different image heights;

FIG. 14A is a cross sectional view of the lenses in an optical system according to a fourth optimized design solution, and FIGS. 14B, 14C, 14D, 14E, and 14F are spot diagrams of this optical system at different image heights;

FIG. 15 is a flow chart of a process performed by an optical system designing system according to another example;

FIG. 16 is a flow chart of a process performed by an optical system designing system according to still another example; and

FIG. 17 is a flow chart of a process performed by an optical system designing system according to still another example.

### DETAILED DESCRIPTION OF THE INVENTION

Prior to description of examples of the present invention, the operation and advantageous effects of an embodiment according to a certain mode of the present invention will be described. To describe the operation and advantageous effects of the embodiment specifically, specific exemplary modes will be described. However, the exemplary modes merely constitute only a portion of the modes encompassed by the present invention, which can include many variations. Therefore, it should be understood that the present invention is not limited by the exemplary modes.

### First Embodiment

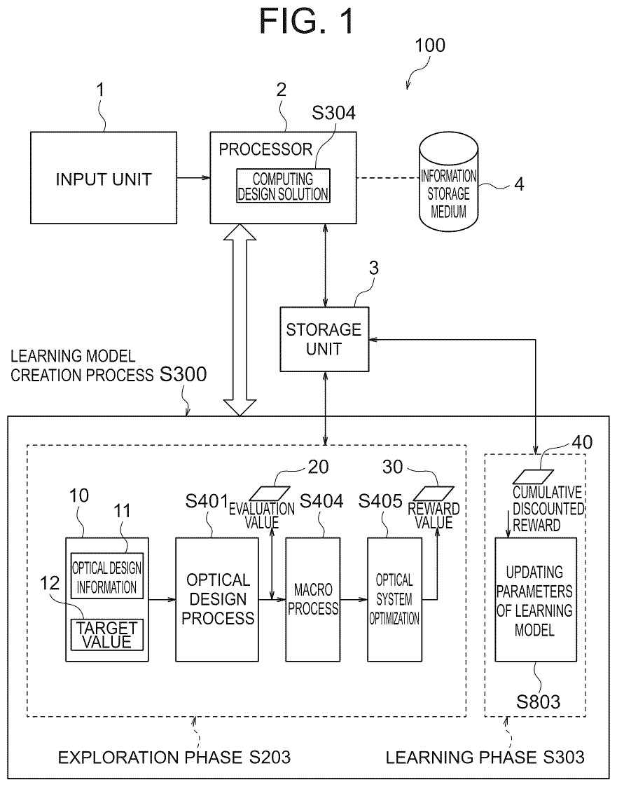

FIG. 1 is a diagram showing the general configuration of an optical system designing system 100 according to a first embodiment. The optical system designing system 100 is a system (or apparatus) that is configured to design optical systems through reinforcement learning.

Firstly, we will describe general concepts used in reinforcement learning and their correspondences with features and processes in the system according to the embodiment. Details are discussed below as appropriate.

Concepts used in reinforcement learning include the following five concepts, (1) agent, (2) environment, (3) state, (4) action, and (5) reward. Correspondences between these five concepts and features or processes in the system according to the embodiment will be described below. The correspondence between these five concepts and the embodiment is shown below.

In reinforcement learning based on the above concepts, an agent acts on the environment to change its state. The agent is given a reward according to the favorableness (or goodness) of the action (in other words, how favorable (or good) the action is). The agent induces the action to increase the reward. Reinforcement learning iterates this process to learn the optimized action.

Correspondences between these concepts in reinforcement learning and elements in the system according to the embodiment will be described in the following.
(1) “Agent” corresponds to a processor.
(2) “Environment” refers to an environment controlled by the agent. The agent acts on the environment and solves a given problem. In this embodiment, the environment corresponds to designing an optical system having desired optical performance through an optical design process.
(3) “State” is information that the environment returns to the agent. In the case of optical design, the state corresponds to numerical data of various factors of an optical system presently designed by reinforcement learning such as curvature radius, air distance, refractive index, focal length, F-number, curvature radius, surface distance, entire length, aberration coefficient, spot diameter, and displacement of the location of the centroid from the location of the spot centroid at a reference wavelength.
(4) “Action” refers to actions that the agent conducts on the environment. In the case of the optical design, the action corresponds to a macro process such as changing the number of lenses.
(5) “Reward” (or reward values in some cases) is a value that the environment returns. The reward is determined by a person who implements the reinforcement learning according to the object and/or environment, for example, to what degree the object is achieved. In the case of optical design according to the embodiment, reward values correspond to values relating to optical performance and/or specifications such as the spot diameter.

There also are concepts other than the above concepts (1) through (5). “Evaluation value” is a value that represents the value of an action or a state, namely a value that represents how favorable the action or state is. The evaluation value takes account of a reward or rewards that will be given in the future. Another concept is “episode”, which refers to a set of processes from the start of an action to the completion of a certain number of actions.

The optical system designing system is configured to design an optical system through reinforcement learning. The optical system designing system includes a storage unit storing at least information relating to a learned model, a processor, and an input unit that inputs optical design information relating to a design of the optical system and a target value to the processor. The learned model is a learning model configured as a function whose parameters have been updated in such a way as a design solution towards the optical design information of the optical system that is based on the target value to compute a design solution towards the optical design information of the optical system that is based on the target value. The processor is configured to execute the processing of: executing a macro process of at least one of the actions of changing the number of lenses included in the optical design information, changing a lens material, changing cementing of lenses, changing the location of a stop, and selecting a spherical lens or an aspherical lens; computing the design information after the execution of the macro process and a reward value based on the target value; computing an evaluation value based on the optical design information and the reward value; and computing a design solution based on the target value in the optical design information.

FIG. 1 shows an optical system designing system 100 that designs optical systems using reinforcement learning. The optical design according to this embodiment is the process of computing (S304) a design solution for an optical system that meets target values 12 starting from initial design data of optical design information 11. A learned model used to compute the design solution is created through the execution of a learning phase S303 and stored in a storage unit 3.

FIG. 1 is a diagram showing an exemplary configuration of the optical system designing system 100 and the process of creating a learning model (S300). The optical system designing system 100 includes a processor 2, an input unit 1 that inputs information on optical system design including optical design information and target values to the processor 2, and a storage unit 3 used to store at least information relating to a learned model. The processor 2 has hardware that controls all the computational processing and input and output of information. The processor 2 performs computation S304 of a design solution through reinforcement learning.

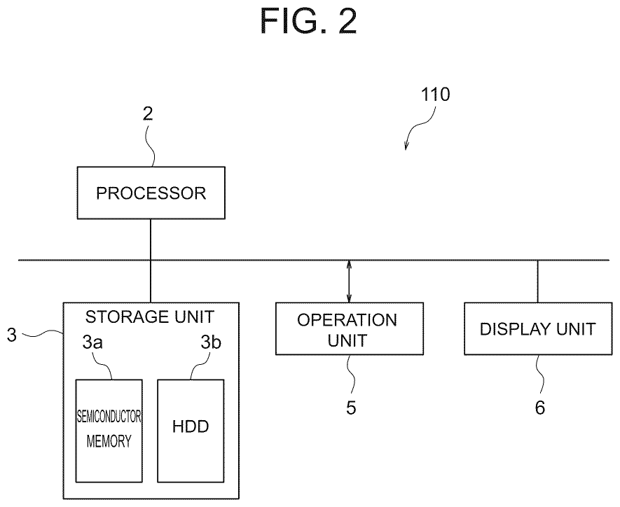

FIG. 2 is a diagram illustrating an exemplary configuration of a learning apparatus 110 that performs the processing of creating a learning model mentioned above. The learning apparatus 110 includes the processor 2, the storage unit 3, and an operation unit 5. The learning apparatus 110 may further include a display unit 6. For example, the learning apparatus 110 is an information processing apparatus such as a personal computer or a server.

The hardware configuration may include not only a local personal computer but also a server that executes required processing.

As described above, the processor 2 is a processor such as a CPU. The processor 2 performs reinforcement learning on the learning model to create a learned model with updated parameters. The storage unit 3 is a storage device such as a semiconductor memory 3a or a hard disk drive 3b. The operation unit 5 includes various operation input devices such as a mouse, a touch panel, or a keyboard. The display unit 6 includes a display unit such as liquid crystal display etc.

In this embodiment, the optical system designing system 100 shown in FIG. 1 also serves as the learning apparatus 110. In this case, the processor 2 and the storage unit 3 also serve as the processor 2 and the storage unit 3 of the optical system designing system 100.

Referring back to FIG. 1, the configuration of the optical system designing system 100 and the process of learning through reinforcement learning will be described in the following.

For example, the input unit 1 is a data interface that receives optical design information 11 and target values 12, which serve as initial design data, a storage interface that reads out initial design data from a storage, or a communication interface that receives optical design information (initial design data) 11 from outside the optical system designing system 100.

Input data 10 includes the optical design information 11 and the target values 12, which serve as initial design data.

The input unit 1 inputs the initial design data it receives to the processor 2 as the optical design information 11.

For example, the storage unit is a storage device, examples of which include a semiconductor memory, a hard disk drive, and an optical disc drive. The storage unit 3 stores a learned model created by the learning model creation process S300 beforehand.

Alternatively, a learned model may be input to the optical system designing system 100 from an external apparatus, such as a server through a network, and the storage unit 3 may store this learned model.

The processor 2 is able to compute a design solution that meets the target values 12 on the basis of the optical design information (initial design data) 11 by performing the design solution computation S304 using the learned model stored in the storage unit 3.

The hardware that constitutes the processor 2 may be a general-purpose processor such as a CPU. In this case, the storage unit 3 stores a program that describes a leaning algorithm and parameters used in the learning algorithm as the learned model.

Alternatively, the processor 2 may be a special purpose processor that is built as hardware that implements a learning algorithm. Examples of such a special purpose processor include an ASIC (Application Specific Integrated Circuit) and an FPGA (Field Programmable Gate Array). In this case, the storage unit 3 stores parameters used in the learning algorithm as the learned model.

A neural network may be used as a function of the learned model. The parameters are weighting coefficients of node-to-node connections in the neural network. The neural network includes at least an input layer to which the optical design information is input, an intermediate layer in which neurons that perform computation on the data input through the input layer are provided, and an output layer that outputs state values and parameters of the probability distribution of policies based on the result of computation output from the intermediate layer.

For example, the intermediate layer of the neural network has a structure including a combination of the following structures (a) through (g):
(a) convolution neural network (CNN)
(b) multi-layer perceptron (MLP)
(c) recurrent neural network (RNN)
(d) gated recurrent unit (GRU)
(e) long short term memory (LSTM)
(f) multi-head attention
(g) transformer.

Two examples of the combination in the intermediate layer are:
(b) multi-layer perceptron+ (e) LSTM, and
(a) convolution neural network+ (b) multi-layer perceptron.

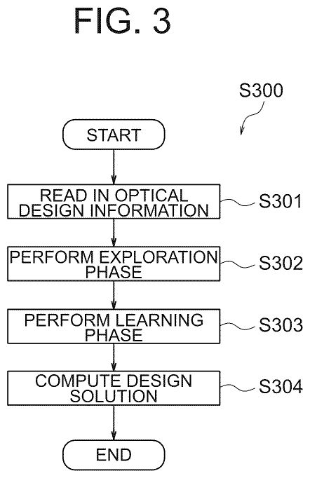

FIG. 3 is a flow chart of the learning model creation process S300. In the optical system designing system 100, the processor 2 that executes the learning model creation process S300 has hardware.

In step S301, the processor 2 reads in the optical design information (initial design data) 11 and the target values 12 from the input unit 1. For example, the optical design information (initial design data) 11 includes information on the curvature radius, the center thickness, and air distance of the lenses and the refractive index of the lens materials. For example, the target values 12 include a value of the spot diameter of the optical system and a value of the refractive index of the lenses.

In step S302, the processing of exploration phase is executed, which will be described later. Data obtained in the exploration phase is stored in the storage unit 3. For example, the data obtained in the exploration phase S302 includes optical design files, evaluation values 20, reward values 30, states (e.g. curvature radii in the designed optical system), and actions (macro processes).

In step S303, parameters of the neural network serving as the learning model are updated based on the cumulative discounted reward 40. The updated parameters are stored in the storage unit 3.

In step S304, the processor 2 computes design solutions of an optical system that attain the target values or values close to the target values. The number of design solutions is not limited to one, but a plurality of design solutions is obtained.

The optical design data (initial design data) 11 may be stored in the storage unit 3 (memory 3a and/or HDD 3b).

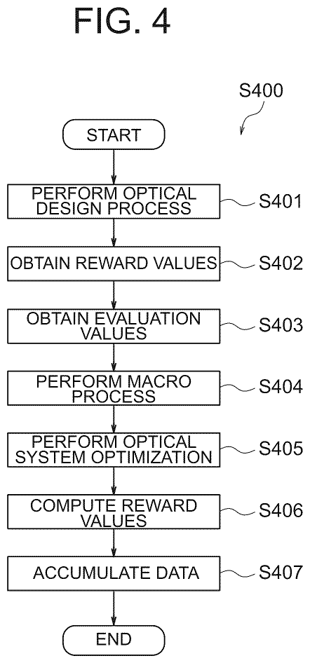

The processing of the exploration phase in an optical system designing method will now be described with reference to FIG. 4.

### (Description of Exploration Phase)

FIG. 4 is a flow chart of the exploration process (exploration phase S400).

The optical design process S401 can be performed by using general-purpose optical design software available in the market or optical design software of user's own development. In step S401, the processor 2 performs the optical design process based on the input data including the optical design information 11 and the target values 12.

In step S402, the processor 2 obtains reward values 30 for the optical design information (or state). The reward values 30 will be described later.

In step S403, the processor 2 computes and obtains evaluation values 20 (state values) for the optical design information (state) from the optical design information (state) and the reward values 30. The evaluation values 20 (state values) will be described later.

In step S404, the processor 2 chooses one macro from some macros prepared in advance and executes it. The macro process S404 will be described later.

In step S405, the processor 2 performs an optical system optimization process S405, where it computes weights for aberrations using an optimization function of the optical design software with weights for aberrations (correction file) prepared in advance.

In step S406, the processor 2 computes reward values 30 for the optical deign information (state) to which the optical optimization process has been applied.

The data obtained in the exploration phase of steps S401 through S406 is stored, or accumulated in the storage unit 3 in step S407.

### (Description of Reward Value)

Now, the reward value will be described. The reward value is calculated using a reward function. The reward value is a value that represents how far the design data after applying the optical system optimization process to an optimum correction file (described later) by the optical design software by executing the macro is from the target value. The reward value is a value that represents the difference between the design data and the target, where if the design data is far from the target value, its value will decrease, and if it is close to the target value, its value will increase.

For example, in the case where a target value is set for the size of the spot diameter, when the size of the spot diameter falls within a predetermined range (in other words, meets the target value), a full score is given. When the target value is not met, a reward value is gin according to a function, example of which is presented below as equation (1). The way of giving reward values is the most important factor in reinforcement learning.

When the target value is not met:

$$reward = exp ( - \frac{{x}^{2}}{{σ}^{2}} ) \qquad ( 1 )$$

When the target value is met:

$$reward = 1 \qquad ( 1 )$$

$$where σ = \frac{target value}{\sqrt{2}} , and$$

$$x = \vert value in present design specifications - target value \vert .$$

Examples of the reward value are as follows.
When the spot diameter at each wavelength and each field is equal to or smaller than F-number×0.6, the reward value is 1. Otherwise, the reward value is determined by the reward function.
When the distance between the location of the centroid of the spot diameter at a reference wavelength and the location of the centroid of the spot diameter at each wavelength is equal to or smaller than F-number×0.6×0.5, the reward value is 1. Otherwise, the reward value is determined by the reward function.
When the surface distance is equal to or larger than a predetermined value, the reward value is 1. Otherwise, the reward value is determined by the reward function.

When all the reward values are 1, a value of 1000 is given as a bonus value. Setting a bonus value advantageously facilitates to learn actions that reach a design that accomplishes target specifications.

In optical design, when rays do not pass through the optical system, it is determined that the design has failed, and then a value of −100 is given as a penalty. Setting a penalty is effective in controlling actions that lead to failure of optical system design in the optical system designing system 100.

The target values to be met are different in their scales (criteria for judgement). For example, the target value for the focal length and the target value for the spot diameter are greatly different in their scales. In this embodiment, a function similar to a Gaussian function is used to keep the scales of the reward values within the range between 0 and 1.

The optical system designing system 100 stores knowledge of an optical designer. For example, the knowledge of an optical designer includes information data (e.g. values that the optical designer monitors during optical designing and measures used to judge the quality of design) and processing data (e.g. macros).

### (Description of State Value)

The evaluation values 200 include state values, action values, and Q values. The evaluation values are used to maximize the cumulative discounted reward.
The cumulative discounted reward will be described later.

The state values computed in step S403 will now be described. Before executing a macro process, the learning apparatus 110 (processor 2) computes state values each time to determine which macro process to choose in the present state to maximize the cumulative discounted reward.

Next, choice of a macro process (action) will be described. For example, in choosing an action, (A) policy iteration or (B) value iteration can be used. The system according to this embodiment uses policy iteration.

### (Description of Policy Iteration)

(A-1) Here, we will describe how a macro process (action) is performed before learning, in other words, before the parameters of the neural network serving as the learning model are updated first time in policy iteration.

An action before learning is determined basically randomly. A macro process (action) is determined according to a probability distribution that serves as a policy. Before the neural network is updated, a macro process (action) is determined according to arbitrary initial parameters (e.g. in the case of normal distribution, average=0 and standard deviation=1).

The parameters of the probability distribution that serves as a policy are determined by values output from the neural network. Every time the parameters of the neural network are updated, the parameters of the probability distribution serving as the policy change. In consequence, the probability distribution changes, and the sampled action also changes.

(A-2) Here, we will describe use of state values in policy iteration.

The processor 2 computes a state value every time it executes a macro process (action). The state value is used to update the parameters of the neural network (in learning phase).

The state value evaluates the parameters of the probability distribution serving as a policy. The state value is used to update the parameters of the neural network so that it will output parameters that make the state value higher.

### (Description of Cumulative Discounted Reward)

Higher state values mean higher expected values of the cumulative discounted reward. The cumulative discounted reward is expressed by following equation (2).

$$R ( τ ) = {\sum }_{t = 0}^{T} {γ}^{t} {r}_{t} , \qquad ( 2 )$$

where γ is the discount rate (<1), and rₜ is the reward in a certain step.

Equation (2) expresses the sum of the rewards for the actions over a predetermined length (T) of trajectory, for example the sum of the rewards for 100 actions in one exploration. Because rewards in the future are uncertain, equation (2) multiplies the rewards in the future by the discount rate γ to make their contributions to the sum smaller.

As above, the system according to the embodiment is configured to update the parameters of the neural network serving as the learning model in such a way as to make the cumulative discounted reward of the reward values larger.

The state values are not used in each macro process (action). Macro processes are determined in the following way.

(A-2-1) A given state is input to the neural network to cause it to output parameters of probability distribution (e.g. the average and the standard deviation in the case of normal distribution).

(A-2-2) The parameters of the probability distribution output from the neural network are applied to the probability distribution serving as a policy. Then, a macro process (action) is determined by sampling.

Sampling based on the probability distribution described above involves some randomness even after the learning phase progresses. Therefore, optimized optical system designs are obtained as multiple solutions from initial value data (or start data) of a single optical system.

Policy iteration requires two neural networks, a neural network for computing state values and a neural network for outputting parameters of probability distributions serving as policies. However, the system according to the embodiment uses one neural network. A portion of this neural network from the input part to the middle is commonly used, and from the middle onward the neural network is split into a neural network for state values and a neural network for policies. The reason why we configured the system in this way is to increase the efficiency of learning by commonly using the process of extracting feature values from states and to compute state values and parameters for actions from the same feature values.

### (Description of Value Iteration)

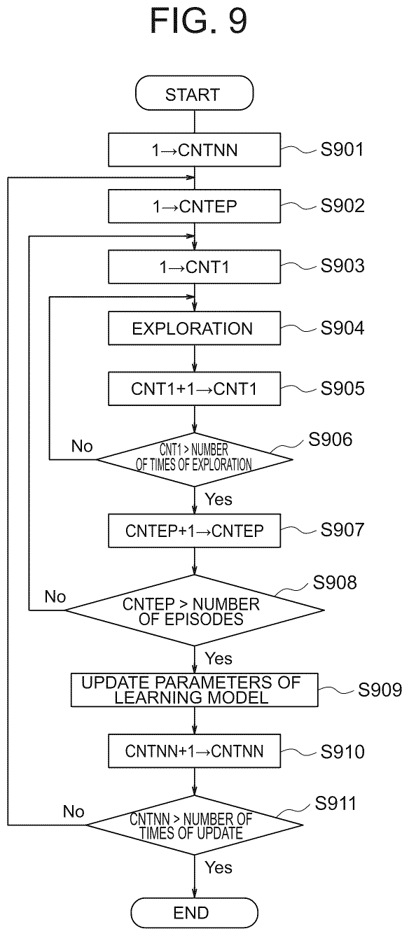

(B-1) Here, we will describe a macro process before learning in value iteration (in other words, a macro process before the neural network is updated first time in step S909 in FIG. 9).

An action is determined randomly according to a certain arbitrary probability distribution (e.g. normal distribution). The parameters of the probability distribution are fixed at this time.

(B-2) Here, we will describe use of state values in value iteration.

A state value is computed every time an action is taken and used to determine an action. The state value used in value iteration is a state-action value, which is more extensive than the state value.

(B-2-1) A given state is input to the neural network to cause it to output state-action values for all the actions in that state, in other words values that will result if specific macro processes are executed with various characteristic values of the optical system presently designed.

(B-2-2) An action given the highest value among the state-action values of respective actions computed as above is chosen. This is called a greedy policy.

In the case of the method that chooses the action given the highest state-action value as in the greedy policy, actions that do not given the highest state-action value are not chosen. Then, new information cannot be obtained, often resulting in an inadequate exploration. To avoid this, it is desirable to use a method that takes a random action at a certain probability a (an E-greedy method).

### (Description of Macro Process)

Next, the macro process S404 will be described. The macro process refers to the process of executing a macro, examples of which will be described below.

The processor 2 receives the state of the present optical design as input data. The processor 2 chooses one action (design operation) among the actions determined as described in the description of policy iteration.

To cause the optical design software to take the chosen action, the design operation is standardized in advance, and a macro for performing the standardized operation is created. It is desirable that a plurality of macros be prepared. The processor 2 causes the optical design software to execute the macro in the background.

What the macro should avoid is a failure of optical design because of that rays do not pass through the optical system. For example in the case where a lens is to be eliminated, to avoid the failure, optimization is performed by deforming the lens gradually into a flat plate, decreasing its thickness at the same time, and to eliminate its surfaces eventually.

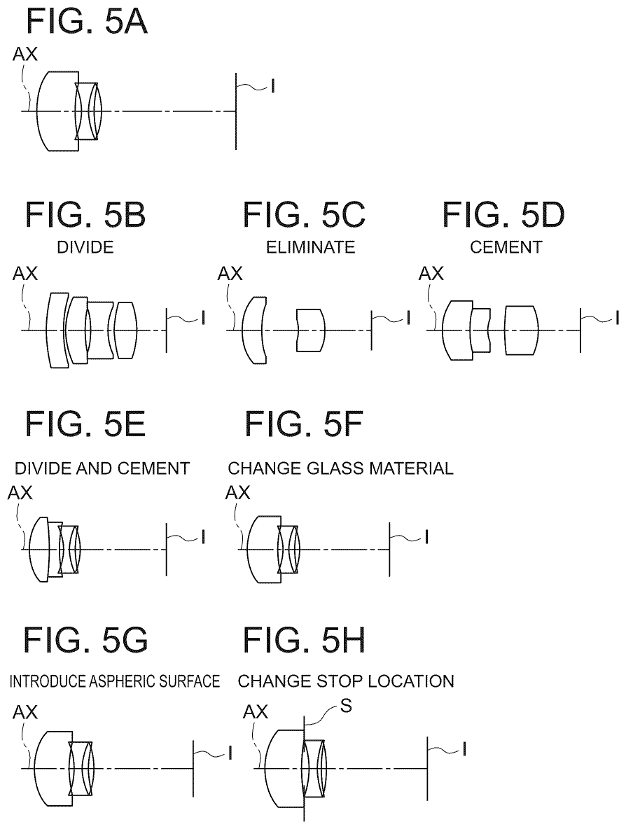

FIGS. 5A, 5B, 5C, 5D, 5E, 5F, 5G, and 5H are cross sectional views of lenses, which respectively illustrate different macro processes. In these drawings, AX indicates the optical axis, I indicates the image plane, and S indicates an aperture stop. After the completion of the macro processes, optimization of the optical system is performed on the lenses shown in FIGS. 5B through 5H, if necessary. The optimization of the optical system will be described later.

FIG. 5A is a cross sectional view of a triplet lens according to initial data.

FIG. 5B is a cross sectional view of the lenses after applying a macro process of dividing the lens closest to the object side into two to the triplet lens shown in FIG. 5A.

FIG. 5C is a cross sectional view of the lenses after applying a macro process of eliminating the second lens (in order from the object side) to the triplet lens shown in FIG. 5A.

FIG. 5D is a cross sectional view of the lenses after applying a macro process of cementing the first and second lenses (in order from the object side) to the triplet lens shown in FIG. 5A.

FIG. 5E is a cross sectional view of the lenses after applying a macro process of dividing the lens closest to the object side into two and cementing them to the triplet lens shown in FIG. 5A.

FIG. 5F is a cross sectional view of the lenses after applying a macro process of changing the glass material of the lens closest to the object side to the triplet lens shown in FIG. 5A.

Examples of the change of the glass material are as follows.
changing the present glass material into a low refractive index, high dispersion glass material
changing the present glass material into a high refractive index, high dispersion glass material
changing the present glass material into a low refractive index, low dispersion glass material
changing the present glass material into a high refractive index, low dispersion glass material

FIG. 5G is a cross sectional view of the lenses after applying a macro process of changing the first surface of the lens closest to the object side into an aspheric surface to the triplet lens shown in FIG. 5A.

FIG. 5H is a cross sectional view of the lenses after applying a macro process of changing the location of the aperture stop S to a position on the image side of the lens closest to the object side to the triplet lens shown in FIG. 5A.

There is another action, an action of doing nothing, though not shown in the drawings.

Referring back to FIG. 4, after executing the macro process S404, the processor 2 performs optimization for aberration correction with weights for aberrations (correction file) prepared in advance using the optimization function of the optical design software in step S405 (optical system optimization process).

When optimization for correcting aberrations of the optical system is performed, the number of items contained in the correction file is very large as compared to problems of reinforcement learning such as joint angle and speed control in problems of robot control. The number of samples that are needed in learning optimization of optical systems is extremely large, specifically tens of millions of samples are considered to be needed. For this reason, in the system according to the embodiment, the task is divided into Bayesian optimization and reinforcement learning.

In the optical designing process and macro processes described above, the processor 2 uses a gradient method in performing optimization of at least one of the curvature radius, the air distance, the refractive index of glass materials at a predetermined wavelength included in the optical design information in optical system designing.

In contrast, in the optical system optimization process (S405) performed after the completion of a macro process, the processor 2 performs an optimization process using a method other than the gradient method at least for the weights for aberrations in optimizing the optical system after executing the macro process. For example, the processor 2 uses Bayesian optimization.

The Bayesian optimization is a method of optimization that determines next candidate points sequentially taking account of expected values of design solutions and uncertainties of the expected values. The Bayesian optimization is often used in machine learning to determine parameters (hyperparameters) set by a person who implements machine learning or in black box optimization.

In the system according to the embodiment, the weights of aberrations that the optical designer uses for aberration correction are regarded as hyperparameters in machine learning. The kinds of aberrations may be selected by the optical designer. Alternatively, the kinds of aberrations may be aberrations set in the system in advance. The values of the weights for the selected aberrations are determined by Bayesian optimization.

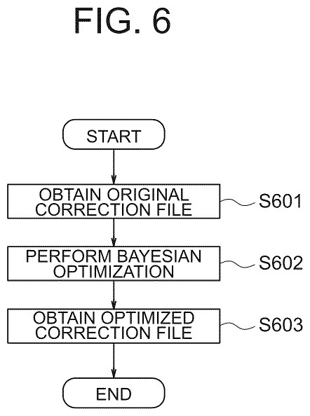

FIG. 6 is a flow chart of the Bayesian optimization. In step S601 of this process, the processor 2 receives an original correction file before optimization of weight values for aberrations. In step S602, the processor 2 performs Bayesian optimization. In step S603, the processor 2 calls the optimized correction file created as above. The optical design software performs aberration correction based on the optimized correction file. The optimized correction file is fixed while the designing operation such as addition and/or elimination of a lens.

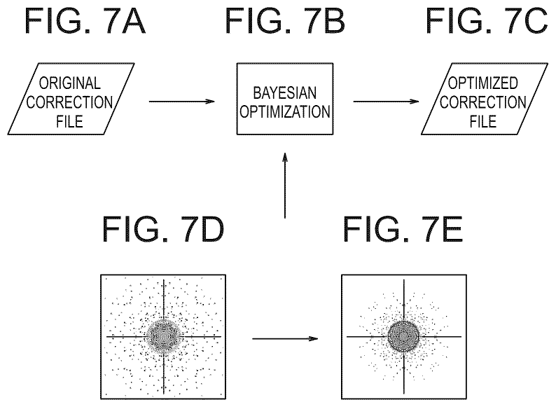

FIGS. 7A, 7B, 7C, 7D, and 7E are diagrams illustrating Bayesian optimization. Firstly, the processor 2 explores for weights for aberrations that minimize the differences between the location of the centroid of the spot diameter (FIG. 7E), the locations of the centroids of the spot diameters at respective wavelengths, the location of the centroid of the spot diameter at a reference wavelength (FIG. 7D), and the locations of the centroids of the spot diameters at respective wavelengths through Bayesian optimization. Then, the processor 2 optimizes the original correction file (FIG. 7A) by Bayesian optimization to create an optimized correction file (FIG. 7C).

Here, we will explain the reason why we use Bayesian optimization and artificial intelligence trained through reinforcement learning. If even the weights for aberrations were controlled through reinforcement learning, the number of variables to be controlled would be too large. Then, the number of samples needed for learning would be extremely large.

This requires a long period of time for learning or a computer having very high performance for computing, for example, a computer that can perform optical computations at high speed and has a large number of cores to allow parallel processing.

For the above reason, we use Bayesian optimization, which has performance advantage in parameter exploration, in exploration and optimization of parameters. We use artificial intelligence trained through reinforcement learning in design operations that are conventionally determined based on experience and intuition of optical designers.

### (Description of Learning Phase)

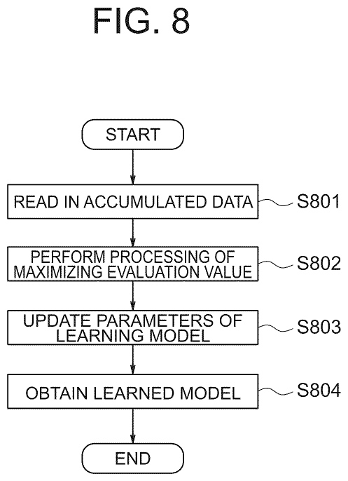

FIG. 8 is a flow chart of a process of creating a learned model.

In step S801, the processor 2 reads in data stored, or accumulated in the storage unit 3. In step S802, the processor 2 performs the processing of maximizing an evaluation value, for example computes a cumulative discounted reward. In step S803, the processor 2 updates the parameters of the neural network serving as a learning model. In step S804, the neural network with the updated parameters is obtained as a learned model. Information on the parameters of the learned model is stored in the storage unit 3.

### (Iteration of Exploration Phase and Learning Phase)

FIG. 9 is a flow chart of iteration of the exploration phase and the learning phase.

In steps S901, S902, and S903 of the process according to the flow chart of FIG. 9, the initial values specified below are input to counter variables (a), (b), and (c).
(a) In step S901, a counter CNTNN of the number of updates of the learning model (neural network) is set to 1 (CNTNN=1).
(b) In step S902, a counter CNTEP of the number of updates of the episode is set to 1 (CNTEP=1).
(c) In step S903, a counter CNT1 of the number of updates of the exploration phase is set to 1 (CNT1=1).

The numbers of iterations are also set. Examples of the number of iterations are as follows, which may be changed as desired.
(d) The number of times of exploration=100.
(e) The number of episodes=10.
(f) The number of updates=100.

Through steps S904, S905, and S906, the exploration in step S904 can be iterated 100 times.

In step S905, the value of CNT1 is incremented by 1.

In step S906, it is determined whether the exploration has been iterated 100 times. When the result of the determination is affirmative (Yes), the process proceeds to step S907. When the result of the determination is negative (No), the process returns to step S904 to perform an exploration.

In step S907, the counter CNTEP of the number of updates of the episode is incremented by 1, and then the process proceeds to step S908.

In step S908, it is determined whether the episode has been iterated 10 times. When the result of the determination is affirmative (Yes), the process proceeds to step S909. When the result of the determination is negative (No), the process returns to step S903 to perform an exploration.

In step S909, the processor 2 updates the neural network.

In step S910, the counter CNTNN of the number of updates of the neural network is incremented by 1, and the process proceeds to step S911.

In step S911, it is determined whether the update of the neural network has been iterated 100 times. When the result of the determination is affirmative (Yes), the process is ended. When the result of the determination is negative (No), the process returns to step S902.

What is performed through the process of steps S901 through S911 is as follows.
Data of one episode is obtained every 100 iterations of exploration.
The neural network is updated once by data of every ten episodes.
The process is ended when the neural network is updated 100 times.

The exploration in step S904 (which is also referred to as exploration phase) is performed a specific number of times that is set is advance (e.g. 100,000 times of exploration and 1,000 episodes). In the learning phase, the parameters of the neural network are updated when data of a predetermined number of episodes (e.g. 1,000 times of exploration and 10 episodes) is accumulated.

### (Computation of Design Solution)

Presented below are examples of design solutions computed through reinforcement learning from input initial optical design information by the optical system designing system 100 described above. Based on one optical design information, multiple design solutions, i.e., design alternatives that achieve the target values, can be computed and displayed, for example, on the display unit 6 (FIG. 2).

A triplet lens having an F-number of 4 is used as initial data.

Target specifications are as follows.

Focal length=9.0 (mm)

F-number=3

Optical performance: a spot diameter≤1.8 (μm), and displacement of the locations of the centroid of spots from the location of centroid at a reference wavelength≤0.9 (μm)

Surface distance ≥0.1 (mm)

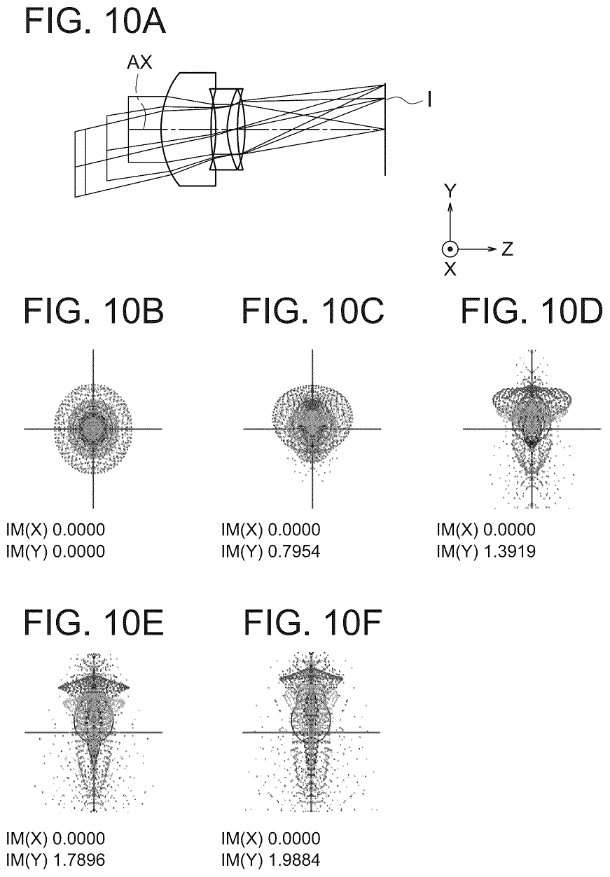

FIG. 10A is a cross sectional view of the lenses in the initial optical system. FIGS. 10B, 10C, 10D, 10E, and 10F are spot diagram at different image heights.

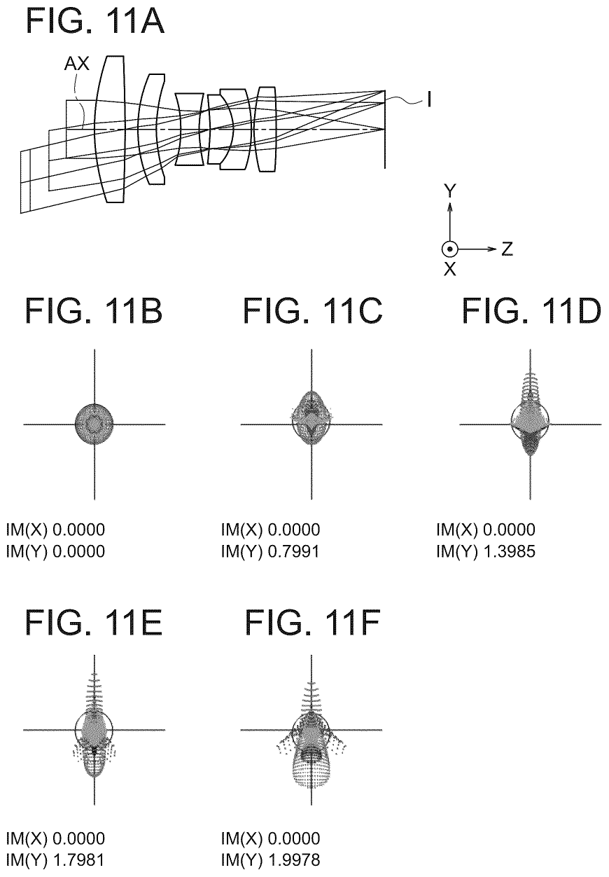

FIG. 11A is a cross sectional view of the lenses in a first optimized optical system. FIGS. 11B, 11C, 11D, 11E, and 11F are spot diagrams of the first optimized optical system at different image heights.

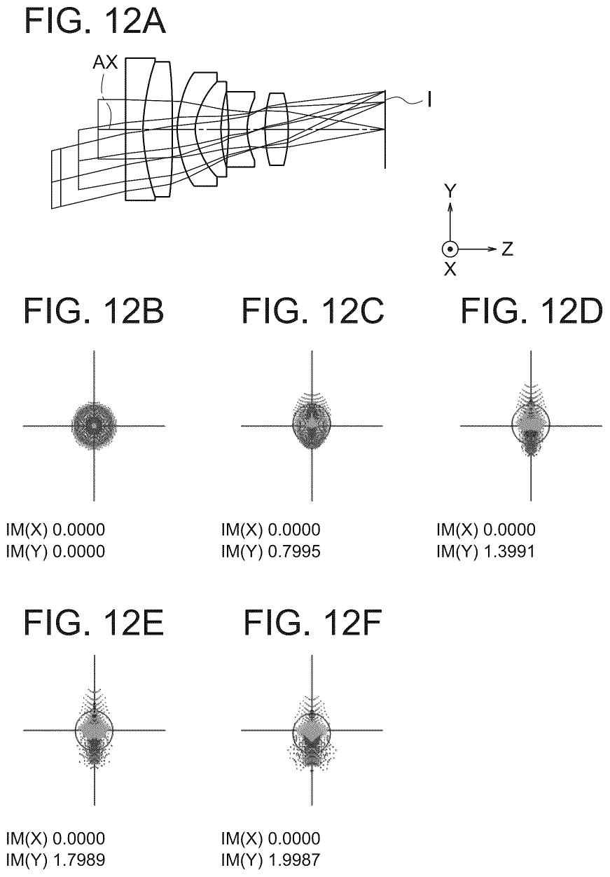

FIG. 12A is a cross sectional view of the lenses in a second optimized optical system. FIGS. 12B, 12C, 12D, 12E, and 12F are spot diagrams of the second optimized optical system at different image heights.

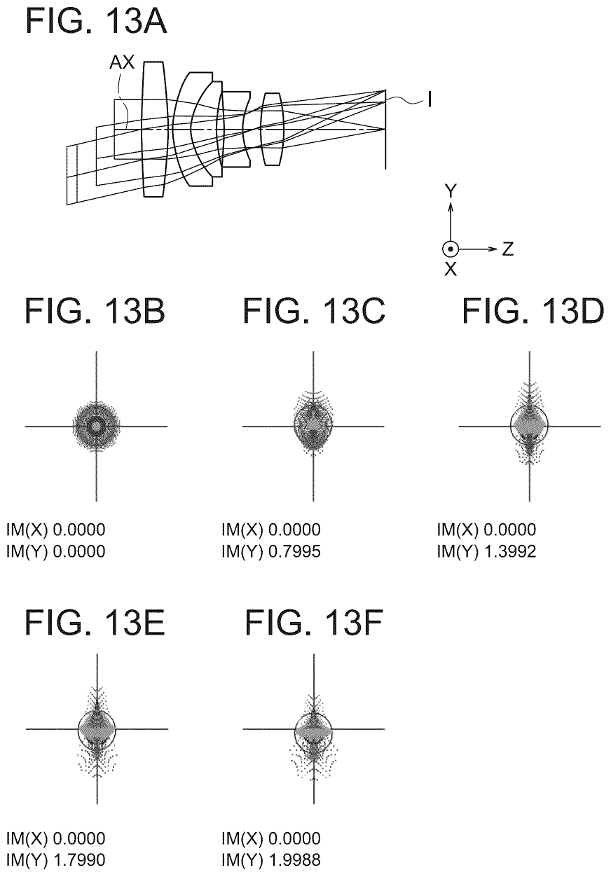

FIG. 13A is a cross sectional view of the lenses in a third optimized optical system. FIGS. 13B, 13C, 13D, 13E, and 13F are spot diagrams of the third optimized optical system at different image heights.

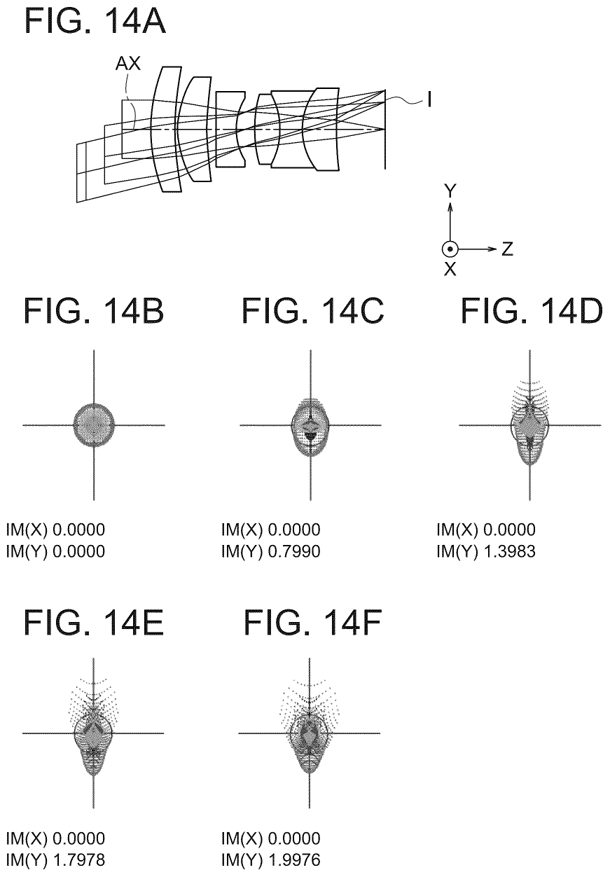

FIG. 14A is a cross sectional view of the lenses in a fourth optimized optical system. FIGS. 14B, 14C, 14D, 14E, and 14F are spot diagrams of the fourth optimized optical system at different image heights.

In FIGS. 10B through 10F, 11B through 11F, 12B through 12F, 13B through 13F, and 14B through 14F, IM (x) and IM (y) are the image heights (in units of millimeter) in the x-y plane.

As will be understood from FIGS. 10B through 10F, 11B through 11F, 12B through 12F, 13B through 13F, and 14B through 14F it is possible to obtain a plurality of optical systems that satisfy the target values.

### (First Modification)

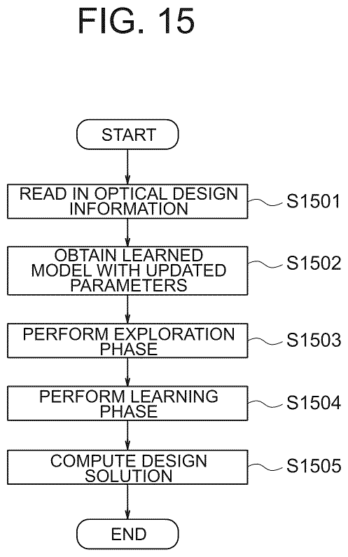

FIG. 15 is a flow chart of a process performed by an optical system designing system according to a first modification of the above embodiment. In step S1501, the processor 2 reads in optical design information (initial design data) 11. In step S1502, the processor 2 obtains a learning model with updated parameters. This learning model may be either stored in the optical system designing system 100 in advance or provided by a user of the optical system designing system 100. In step S1503, the processor 2 performs the processing of exploration phase. In step S1504, the processor 2 further performs the processing of learning phase, when necessary. In step S1505, the processor 2 computes a design solution.

In the system according the first modification, the storage unit 3 stores optimized optical design information at least after the completion of the macro process.

### (Second Modification)

The processor 2 can read a learned model provided from outside the optical system designing system by the user, or a learning model with updated parameters provided by the user is stored in the storage unit 3.

In the case of a second modification, a learned model is also prepared in another form such as a file. In some cases, a learned model is provided by a software sharer from a server in response to a user's request.

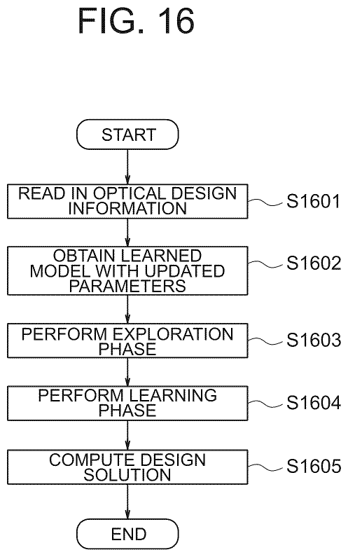

FIG. 16 is a flow chart of a process performed by an optical system designing system according to the second modification of the above embodiment. In step S1601, the processor 2 reads in optical design information (initial design data) 11. In step S1602, the processor 2 obtains a learning model with updated parameters provided by the user. In step S1603, the processor 2 performs the processing of exploration phase. In step S1604, the processor 2 performs the processing of learning phase. In step S1605, the processor 2 computes a design solution.

### (Third Modification)

The storage unit 3 stores a learning model with updated parameters. The learning model with updated parameters may be provided by either the user or the optical system designing system. After the completion of the exploration phase, the processor 2 computes a design solution without further learning. In other words, the processor 2 computes a design solution using the learning model with updated parameters without further updating its parameters.

In this case, though the processing of learning phase is not performed, the processor 2 calls an updated learned model, performs an exploration, and computes a design solution from data collected through the exploration.

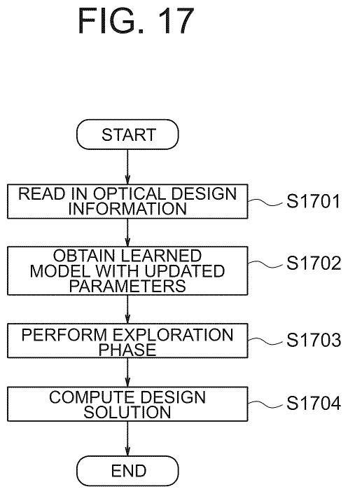

FIG. 17 is a flow chart of a process performed by an optical system designing system according to a third modification of the above embodiment. In step S1701, the processor 2 reads in optical system information (initial design data) 11. In step S1702, the processor 2 obtains a learned model with updated parameters. In step S1703, the processor 2 performs the processing of exploration phase to accumulate data. In step S1704, the processor 2 computes a design solution from accumulated design files.

The system according to the embodiment described above can efficiently performs exploration an extremely large number of times that can hardly be fulfilled by optical designers to create multiple design solutions having different configurations that meet required specifications. The system according to the embodiment can efficiently create many design plans in a short time with good prospects.

Although an optical system designing system and an optical system designing method have been described in the description of the embodiment, a process similar to the process implemented by the optical system designing system and the optical system designing method can also be implemented by a learned model, a program, and an information recording medium as described below.

A learned model according to at least some embodiments of the present invention is configured to allow a computer configured to design optical systems through reinforcement learning to operate. The learned model is learned by:

obtaining optical design information relating to a design of an optical system and a target value;

executing a macro process of at least one of the actions of changing the number of lenses included in the optical design information, changing a lens material, changing cementing of lenses, changing the location of a stop, and selecting a spherical lens or an aspherical lens;

computing optical design information after the execution of the macro process and a reward value based on a target value;

performing an exploration to compute an evaluation value based on the optical design information and the reward value; and

updating parameters of a learning model based on the evaluation value in such a way as to maximize the evaluation value.

An information storage medium 5 (shown in FIG. 1) according to at least some of embodiments of the present invention stores a learned model and a program. The program is configured to cause a computer to execute the step of:

inputting optical design information relating to a design of an optical system and a target value;

executing a macro process of at least one of the actions of changing the number of lenses included in the optical design information, changing a lens material, changing cementing of lenses, changing the location of a stop, and selecting a spherical lens or an aspherical lens;

computing optical design information after the execution of the macro process and a reward value based on the target value;

computing an evaluation value based on the optical design information and the reward value; and

computing a design solution towards the optical design information of the optical system that is based on the target value using the learned model.

The learned model is a learning model configured as a function whose parameters have been updated so as to compute a design solution towards the optical design information of the optical system that is based on the target value.

While an embodiment of the present invention and its modification have been described, it should be understood that the present invention is not limited to the embodiment or the modifications, but in embodiments, one or more features can be modified without departing from the scope of the present invention when it is implemented actually. It is possible to make various inventions by employing two or more features described in the above descriptions of the embodiment and modifications in suitable combinations. For example, one or more features among all the features described in the above descriptions of the embodiment and modifications may be eliminated. Two or more features described in the descriptions of different embodiment or modifications may be employed in suitable combinations. As above, various modifications and applications can be made without departing from the essence of the present invention.

As above, the present invention is suitably applied to an optical system designing system, an optical system designing method, a learned model, and an information recording medium that are used to efficiently create many design plans in a short time with good prospects by choosing an optimization function of optical design software and various methods such as increasing or decreasing the number of lenses.

According to the present invention, it is possible to provide an optical system designing system, an optical system designing method, a learned model, and an information recording medium that can efficiently create a plurality design plans in a short time with good prospects by choosing an optimization function of optical design software and various methods such as increasing or decreasing the number of lenses through reinforcement learning.

What is claimed is:

1. An optical system designing system for designing an optical system through reinforcement learning, comprising:
a storage unit storing at least information relating to a learned model;
a processor; and
an input unit that inputs optical design information relating to a design of the optical system and a target value to the processor,
the learned model being a learning model configured as a function whose parameters have been updated in such a way as to compute a design solution towards the optical design information of the optical system that is based on the target value, and
the processor configured to execute the processing of:
executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values;
computing the design information after the execution of the macro process and a reward value based on the target value;
computing an evaluation value based on the optical design information and the reward value; and
computing a design solution based on the target value in the optical design information.

2. An optical system designing system according to claim 1, wherein the processor updates parameters of the learning model in such a way as to increase a cumulative discounted reward of the reward value.

3. An optical system designing system according to claim 1, wherein when designing the optical system, the processor performs optimization of at least one of a curvature radius, an air distance, a refractive index of a glass material at a specific wavelength in the optical design information using a gradient method.

4. An optical system designing system according to claim 1, wherein the storage unit stores optimized optical design information at least after execution of the macro process.

5. An optical system designing system according to claim 1, wherein the processor is able to read a learned model provided from outside the optical system designing system, or the storage unit stores a learned model with updated parameters.

6. An optical system designing system according to claim 1, wherein the storage unit stores a learned model with updated parameters, and the processor computes the design solution using the learned model with undated parameters without further updating its parameters.

7. An optical system designing method for designing an optical system through reinforcement learning, comprising the steps of:
storing at least information relating to a learned model;
obtaining optical design information relating to a design of the optical system and a target value, the learned model being a learning model configured as a function whose parameters have been updated in such a way as to compute a design solution towards the optical design information of the optical system that is based on the target value;
executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values;
computing the optical design information after the execution of the macro process and a reward value based on the target value;
computing an evaluation value based on the optical design information and the reward value; and
computing a design solution towards the optical design information of the optical system that is based on the target value.

8. An optical system designing method according to claim 7, comprising the step of performing an optimization by a method other than a gradient method for at least the weights for aberrations in the optimization of the optical system after the execution of the macro process.

9. An optical system designing method according to claim 7, comprising the step of updating parameters of the learning model in such a way as to increase a cumulative discounted reward of the reward value.

10. A learned model configured to allow a computer configured to design an optical system through reinforcement learning to operate, the learned model being learned by:
obtaining optical design information relating to a design of an optical system and a target value;
executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values;
computing the optical design information after the execution of the macro process and a reward value based on the target value;
performing an exploration to compute an evaluation value based on the optical design information and the reward value; and
updating parameters of a learning model based on the evaluation value in such a way as to maximize the evaluation value.

11. An information storage medium storing a learned model and a program,
the program being configured to cause a computer to execute the step of:
inputting optical design information relating to a design of an optical system and a target value;
executing a macro process of at least one of the actions of changing the number of lenses included in the optical design information, changing a lens material, changing cementing of lenses, changing the location of a stop, and selecting a spherical lens or an aspherical lens and performing an optical system optimization process using weights for aberrations computed by Bayesian optimization as correction values;
computing the optical design information after the execution of the macro process and a reward value based on the target value;
computing an evaluation value based on the optical design information and the reward value; and
computing a design solution towards the optical design information of the optical system that is based on the target value using the learned model, the learned model being a learning model configured as a function whose parameters have been updated in such a way as to compute a design solution towards the optical design information of the optical system that is based on the target value.
